(19) United States
(12) Patent Application Publication
(10) Pub. No.: US 2021/0407830 A1
(43) Pub. Date: Dec. 30, 2021

(54) MICRO-LED POSITIONING ERROR CORRECTING CARRIER AND MICRO-LED TRANSFER SYSTEM

(71) Applicant: POINT ENGINEERING CO., LTD., Asan (KR)

(72) Inventors: Bum Mo AHN, Suwon (KR); Seung Ho PARK, Hwaseong (KR); Sung Hyun BYUN, Hwaseong (KR)

(21) Appl. No.: 17/291,981

(22) PCT Filed: Nov. 5, 2019
(86) PCT No.: PCT/KR2019/014921

§ 371 Date: May 6, 2021

(30) Foreign Application Priority Data
Nov. 9, 2018 (KR) 10-2018-0137230

(51) Int. Cl. H01L 21/67; H01L 25/075; H01L 21/683; H01L 21/68

(52) U.S. Cl. CPC H01L 21/67144; H01L 21/68; H01L 21/6838; H01L 25/0753

(57) ABSTRACT

Proposed are a micro-LED position error correcting carrier capable of correcting a position error of micro-LEDs, and a micro-LED transfer system using the same. The micro-LED position error correcting carrier includes: a loading recess having a bottom surface and an inclined portion and allowing a micro-LED to be accommodated therein; and a non-loading surface provided around the loading recess.

### TECHNICAL FIELD

The present disclosure relates to a micro-LED position error correcting carrier for correcting the positions of micro-LEDs, and a micro-LED transfer system having the same.

### BACKGROUND ART

Currently, the display market remains dominated by LCDs, but OLEDs are quickly replacing LCDs and emerging as mainstream products. In the current situation in which display makers are rushing to participate in the OLED market, micro light-emitting diode (hereinafter, referred to as ‘micro-LED’) displays have emerged as another type of next generation display. A micro-LED is not a package type covered with molding resin or the like, but a piece obtained by cutting out a wafer used for crystal growth. Liquid crystal and organic materials are the core materials of LCDs and OLEDs, respectively, whereas the micro-LED display uses 1 μm to 100 μm LED chips themselves as a light emitting material.

Since the term “micro-LED” emerged in a patent “MICRO-LED ARRAYS WITH ENHANCED LIGHT EXTRACTION” in 1999 (Korean Patent No. 10-0731673) disclosed by Cree Inc., related research papers based thereon were subsequently published. In order to apply micro-LEDs to a display, it is necessary to develop a customized microchip based on a flexible material and/or a flexible device using a micro-LED device, and techniques of transferring micrometer-sized LED chips and accurately mounting the LED chips on a display pixel electrode are required.

Particularly, with regard to the transfer of the micro-LED device to a display substrate, as the LED size is reduced to 1 to 100 micrometers (μm), it is impossible to use a conventional pick-and-place machine, and a technology of a transfer head for higher precision is required. With respect to such a technology of a transfer head, several structures have been proposed as described below.

Luxvue Technology Corp., USA, proposed a method of transferring a micro-LED using an electrostatic head (Korean Patent Application Publication No. 10-2014-0112486). A transfer principle of this patent document is that a voltage is applied to a head unit made of a silicone material so that the head unit comes into close contact with a micro-LED due to electrification.

X-Celeprint Limited, USA, proposed a method of using an elastic polymer material as a transfer head and transferring micro-LEDs positioned on a wafer to a desired substrate (Korean Patent Application Publication No. 10-2017-0019415).

Korea Photonics Technology Institute proposed a method of transferring a micro-LED using a ciliary adhesive-structured head (Korean Patent No. 10-1754528).

Korea Institute of Machinery and Materials has proposed a method of transferring a micro-LED using a roller coated with an adhesive (Korean Patent No. 10-1757404).

Samsung Display Co., Ltd proposed a method of transferring micro-LEDs to an array substrate according to electrostatic induction by applying a negative voltage to first and second electrodes of the array substrate in a state in which the array substrate is immersed in a solution (Korean Patent Application Publication No. 10-2017-0026959).

LG Electronics Inc. proposed a method in which a head holder is disposed between multiple pick-up heads and a substrate and a shape of the head holder is deformed by movement of the multiple pick-up heads such that the multiple pick-up heads are allowed to move freely (Korean Patent Application Publication No. 10-2017-0024906).

However, even if a micro-LED transfer head having high accuracy is used, a transfer error problem occurs due to a position error in alignment of micro-LEDs on a first substrate on which the micro-LEDs are provided. Specifically, if there exists the position error in the alignment of the micro-LEDs on the first substrate, when a transfer head holds the micro-LEDs of the first substrate, the transfer head holds micro-LEDs having a position error. This leads to a transfer error in which even if manufacturing yield of bonding pads on a second substrate to which the micro-LEDs are transferred is high, each of the micro-LEDs fails to be accurately positioned on an associated one of the bonding pads.

FIG. 1 is a view schematically illustrating a technology underlying the present disclosure. As illustrated in FIG. 1, a transfer head 1000 holds micro-LEDs 100 on a first substrate 1001. In this case, the transfer head 1000 has high precision, and bonding pads 1002a of a second substrate 1002 have high alignment accuracy. Meanwhile, the micro-LEDs 100 on the first substrate 1001 are in a state in which a position error exists in the alignment thereof. When the transfer head 1000 holds the micro-LEDs 100 of the first substrate 1001, the transfer head 1000 holds micro-LEDs 100 having a position error. Thereby, when the micro-LEDs 100 are transferred to upper surfaces of the bonding pads 1002a on the second substrate 1002, an alignment error problem occurs between the micro-LEDs 100 and the bonding pads 1002a. This results in producing defective products.

In other words, even if the transfer precision of the transfer head 1000 is high and the manufacturing yield of the bonding pads 1002a on the second substrate 1002 is high, an alignment error occurs after transfer if there exists a position error in the alignment of the micro-LEDs 100 on the first substrate 1001 on which the micro-LEDs 100 are provided. Such an error results in defects.

### Documents of Related Art

### Patent Document 1

(Patent Document 1) Korean Patent No. 10-0731673

(Patent Document 2) Korean Patent Application Publication No. 10-2014-0112486

(Patent Document 3) Korean Patent Application Publication No. 10-2017-0019415

(Patent Document 4) Korean Patent No. 10-1754528

(Patent Document 5) Korean Patent No. 10-1757404

(Patent Document 6) Korean Patent Application Publication No. 10-2017-0026959

(Patent Document 7) Korean Patent Application Publication No. 10-2017-0024906

### DISCLOSURE

### Technical Problem

Accordingly, the present disclosure has been made keeping in mind the above problems occurring in the related art, and an objective of the present disclosure is to provide a micro-LED position error correcting carrier for correcting a position error of micro-LEDs before the micro-LEDs are transferred to a second substrate, so that when the micro-LEDs are transferred to the second substrate and mounted, an alignment error between the micro-LEDs and bonding pads on the second substrate, and to provide a micro-LED transfer system.

### Technical Solution

According to one aspect of the present disclosure, there is provided a micro-LED position error correcting carrier, including: a loading recess having a bottom surface and an inclined portion and allowing a micro-LED to be accommodated therein; and a non-loading surface provided around the loading recess.

Furthermore, the bottom surface may hold the micro-LED using holding force.

Furthermore, the holding force may be at least one of vacuum suction force, Van der Waals force, electrostatic force, and magnetic force.

According to another aspect of the present disclosure, a micro-LED position error correcting carrier, including: a guide member having an inclined portion and a non-loading surface; and a support member coupled to a lower portion of the guide member to form the loading recess by closing a lower end of the inclined portion.

Furthermore, the support member may hold a micro-LED using holding force.

Furthermore, the support member may include a porous member having arbitrary or vertical pores, and the support member may vacuum-hold a micro-LED by applying a vacuum to the pores.

Furthermore, the guide member may be made of an elastic material.

According to still another aspect of the present disclosure, there is provided a micro-LED transfer system, including: a transfer head configured to transfer micro-LEDs; and a micro-LED position error correcting carrier including a loading recess that has a bottom surface and an inclined portion and allows a micro-LED to be accommodated therein, and a non-loading surface provided around the loading recess, wherein among the micro-LEDs held on the transfer head, a micro-LED corresponding to the loading recess may be transferred to the micro-LED position error correcting carrier, while a micro-LED corresponding to the non-loading surface may not be transferred to the micro-LED position error correcting carrier.

According to still another aspect of the present disclosure, there is provided a micro-LED transfer system, including: a substrate on which micro-LEDs are provided; and a micro-LED position error correcting carrier including: a loading recess that has a bottom surface and an inclined portion and allows a micro-LED to be accommodated therein, and a non-loading surface provided around the loading recess, wherein among the micro-LEDs provided on the substrate, a micro-LED corresponding to the loading recess may be transferred to the micro-LED position error correcting carrier, while a micro-LED corresponding to the non-loading surface may not be transferred to the micro-LED position error correcting carrier.

According to still another aspect of the present disclosure, there is provided a micro-LED transfer system, including: a micro-LED position error correcting carrier including a loading recess that has a bottom surface and an inclined portion and allows a micro-LED to be accommodated therein, and a non-loading surface provided around the loading recess; a circuit board on which a bonding pad connected to a terminal of the micro-LED is provided; and a transfer head configured to transfer the micro-LED seated on the micro-LED position error correcting carrier to the circuit board.

### Advantageous Effects

As described above, the micro-LED position error correcting carrier and micro-LED transfer system according to the present disclosure can correct a position error of micro-LEDs before transferring the micro-LEDs to a second substrate, thereby minimizing an alignment error between the micro-LEDs and bonding pads. Thereby, it is possible to achieve an effect of minimizing mass production of defective products and improving micro-LED transfer efficiency.

### DESCRIPTION OF DRAWINGS

FIG. 1 is a view schematically illustrating a technology underlying the present disclosure.

FIG. 2 is a view illustrating micro-LEDs to be transferred by the present disclosure.

FIG. 3 is a view illustrating a micro-LED position error correcting carrier according to an exemplary embodiment of the present disclosure.

FIG. 4 is a view illustrating the micro-LED position error correcting carrier according to the exemplary embodiment of the present disclosure as viewed from above.

FIG. 5 is a view illustrating a holding surface of a transfer head on which micro-LEDs of a first substrate are held as viewed from below.

FIGS. 6A to 6D, 7A to 7E and 8A to 8C are views schematically illustrating a micro-LED transfer system according to the present disclosure.

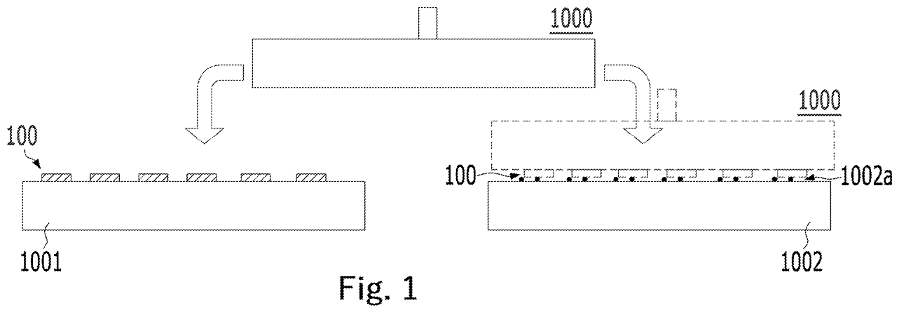

### MODE FOR INVENTION

Contents of the description below merely exemplify the principle of the present disclosure. Therefore, those of ordinary skill in the art may implement the theory of the present disclosure and invent various apparatuses which are included within the concept and the scope of the invention even though it is not clearly explained or illustrated in the description. Furthermore, in principle, all the conditional terms and embodiments listed in this description are clearly intended for the purpose of understanding the concept of the present disclosure, and one should understand that this invention is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views which schematically illustrate ideal embodiments of the present disclosure. For explicit and convenient description of the technical content, thicknesses and widths of regions and diameters of holes in the figures may be exaggerated. Therefore, variations from the shapes of the illustrations as a result, for example, of manufacturing techniques and/or tolerances, are to be expected. In addition, a limited number of micro-LEDs are illustrated in the drawings. Thus, the embodiments should not be construed as limited to the particular shapes of regions illustrated herein but are to include deviations in shapes that result, for example, from manufacturing.

In describing various embodiments, the same reference numerals will be used throughout different embodiments and the description to refer to the same or like elements or parts. In addition, the configuration and operation already described in other embodiments will be omitted for convenience.

Hereinafter, exemplary embodiments of the present disclosure will be described in detail with reference to the accompanying drawings.

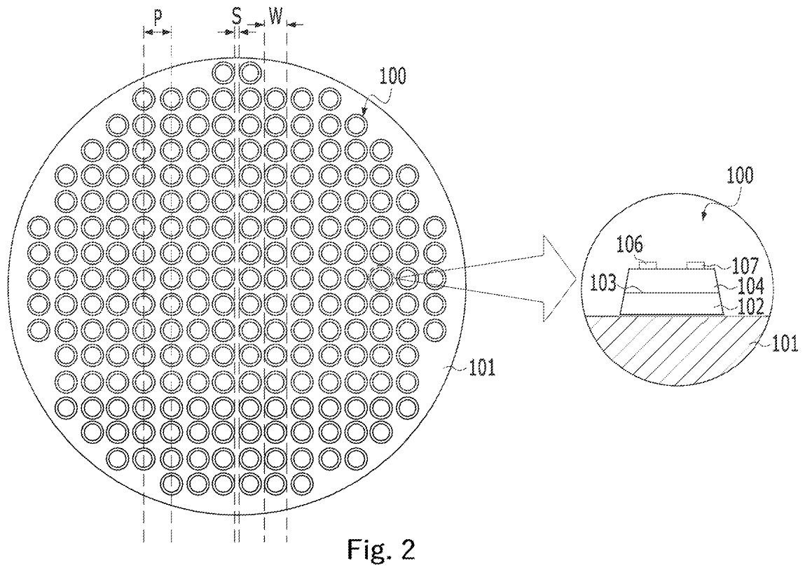

FIG. 2 is a view illustrating multiple micro-LEDs 100 having position errors to be corrected by a micro-LED position error correcting carrier according to an exemplary embodiment of the present disclosure. The micro-LEDs 100 are fabricated and disposed on a growth substrate 101.

The growth substrate 101 may be embodied by a conductive substrate or an insulating substrate. For example, the growth substrate 101 may be made of at least one selected from among the group consisting of sapphire, SiC, Si, GaAs, GaN, ZnO, Si, GaP, InP, Ge, and Ga₂O₃.

Each of the micro-LEDs 100 may include: a first semiconductor layer 102; a second semiconductor layer 104; an active layer 103 provided between the first semiconductor layer 102 and the second semiconductor layer 104; a first contact electrode 106; and a second contact electrode 107. The first semiconductor layer 102, the active layer 103, and the second semiconductor layer 104 may be formed by performing metalorganic chemical vapor deposition (MOCVD), chemical vapor deposition (CVD), plasma-enhanced chemical vapor deposition (PECVD), molecular-beam epitaxy (MBE), hydride vapor phase epitaxy (HVPE), or the like.

The first semiconductor layer 102 may be implemented, for example, as a p-type semiconductor layer. A p-type semiconductor layer may be made of a semiconductor material having a composition formula of InxAlyGa1-x-yN (0≤x≤1, 0≤y≤1, 0≤x+y≤1) selected from among, for example, GaN, AlN, AlGaN, InGaN, InN, InAlGaN, AlInN, and the like, and the layer may be doped with a p-type dopant such as Mg, Zn, Ca, Sr, or Ba. The second semiconductor layer 104 may be implemented, for example, as an n-type semiconductor layer. An n-type semiconductor layer may be made of a semiconductor material having a composition formula of InxAlyGa1-x-yN (0≤x≤1, 0≤y≤1, 0≤x+y≤y1) selected from among, for example, GaN, AlN, AlGaN, InGaN, InN, InAlGaN, AlInN, and the like, and the layer may be doped with an n-type dopant such as Si, Ge, or Sn.

However, the present disclosure is not limited to this. The first semiconductor layer 102 may be implemented as an n-type semiconductor layer, and the second semiconductor layer 104 may be implemented as a p-type semiconductor layer.

The active layer 103 is a region where electrons and holes are recombined. As the electrons and the holes are recombined, the active layer 103 transits to a low energy level and generates light having a wavelength corresponding thereto. The active layer 103 may be made of a semiconductor material having a composition formula of InxAlyGa1-x-yN (0≤x≤1, 0≤y≤1, 0≤x+y≤y1) and may have a single quantum well structure or a multi quantum well (MQW) structure. In addition, the active layer 103 may have a quantum wire structure or a quantum dot structure.

The first contact electrode 106 and the second contact electrode 107 may be provided on the first semiconductor layer 102. The first contact electrode 106 and/or the second contact electrode 107 may be made of various conductive materials including a metal, conductive oxide, and conductive polymer.

In FIG. 2, the letter “P” denotes a pitch distance between the micro-LEDs 100, “S” denotes a separation distance between the micro-LEDs 100, and “W” denotes a width of each micro-LED 100.

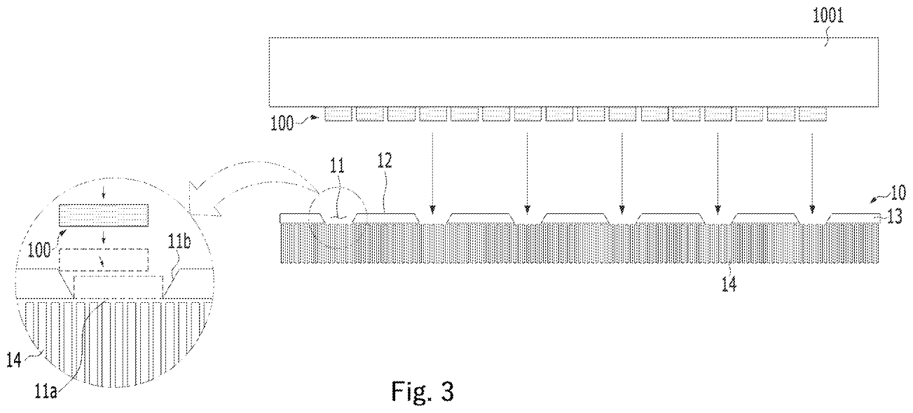

FIG. 3 is a view illustrating the micro-LED position error correcting carrier 10 according to the exemplary embodiment of the present disclosure.

The micro-LED position error correcting carrier 10 may receive micro-LEDs 100 from a transfer head 1000 or a first substrate 1001 such as a growth substrate or a temporary substrate. The micro-LED position error correcting carrier 10 may correct alignment positions of the micro-LEDs 100. Thereby, when transferring the micro-LEDs 100 onto a second substrate 1002 (e.g., a circuit board) provided with bonding pads 1002a, there is obtained an effect of minimizing an alignment error between the micro-LEDs 100 and the bonding pads 1002a.

In transferring the micro-LEDs 100 to the second substrate 1002, if the alignment of the micro-LEDs 100 on the first substrate 1001 is not correct, there occurs a problem in that a defect occurs even if transfer precision of the transfer head 1000 or alignment accuracy of the bonding pads 1002a on the second substrate 1002 are high. Therefore, it is important to correct the alignment positions of the micro-LEDs 100 on the first substrate 1001 before transferring the micro-LEDs 100 to the second substrate 1002. The micro-LED position error correcting carrier 10 according to the present disclosure may include a loading recess 11 having a bottom surface 11a and an inclined portion 11b. By accommodating a corresponding one of the micro-LED 100 in the loading recess 11 having the inclined portion 11b, the present disclosure may accurately correct the alignment positions of the micro-LEDs 100 before the micro-LEDs 100 are transferred to the second substrate 1002. In this case, the micro-LED position error correcting carrier 10 may directly receive the micro-LEDs 100 of the first substrate 1001 to correct a position error thereof. Alternatively, the micro-LED position error correcting carrier 10 may receive the micro-LEDs 100 from the transfer head 1000 on which the micro-LEDs 100 of the first substrate 1001 are held to correct a position error thereof.

Hereinafter, a detailed description will be given with reference to the accompanying drawings.

As illustrated in FIG. 3, the micro-LED position error correcting carrier 10 may include the loading recess 11 and a non-loading surface 12. The micro-LED position error correcting carrier 10 may correct a position error of micro-LEDs 100 received from the transfer head 1000 or the first substrate 1001. A member which is provided spaced apart above the micro-LED position error correcting carrier 10 illustrated in FIG. 3 may be the transfer head 1000 or the first substrate 1001. In addition, the micro-LEDs 100 provided on the transfer head 1000 or the first substrate 1001 may be red, green, or blue micro-LEDs 100a, 100b, or 100c.

The loading recess 11 may have the bottom surface 11a and the inclined portion 11b. The loading recess 11 accommodates a corresponding one of the micro-LEDs 100 received from the transfer head 1000 or the first substrate 1001.

The bottom surface 11a of the loading recess 11 has a width smaller than that of the inclined portion 11b. The bottom surface 11a may have a width smaller than that of the inclined portion 11b and equal to that of each of the micro-LEDs 100. Thereby, the micro-LED 100 may be guided to the inclined portion 11b and seated on the bottom surface 11a, so that the position thereof is precisely corrected.

The inclined portion 11b has a width larger than that of the bottom surface 11a. As the inclined portion 11b has a larger width that the bottom surface 11a, an inclination angle is formed between the inclined portion 11b and the bottom surface 11a. The inclined portion 11b is inclined so that the width thereof gradually increases upward with respect to the bottom surface 11a. Thereby, the inclined portion 11b serves to guide each of the micro-LEDs 100 detached from the transfer head 1000 or the first substrate 1001 to the bottom surface 11a. Specifically, the micro-LED 100 may be guided to the bottom surface 11a to be seated thereon. Referring to an enlarged view of a part of the loading recess 11 illustrated in FIG. 3, the detached micro-LED 100 falls in a direction toward the bottom surface 11a of the loading recess 11. When falling, the micro-LED 100 is in a state of having a position error. The inclined portion 11b is configured so that the width thereof gradually decreases toward the bottom surface 11a. Thereby, the micro-LED 100 that has entered within a width range of the inclined portion 11b is accurately seated on an upper surface of the bottom surface 11a while the position error with respect to the bottom surface 11a is reduced.

When the width of the inclined portion 11b is larger than that of the bottom surface 11a, the range that can accommodate the position error between the loading recess 11 and the micro-LED 100 increases when the micro-LED 100 is accommodated in the loading recess 11. Specifically, the inclined portion 11b extends upward from the bottom surface 11a to thereby form an opening of the loading recess 11. The opening of the loading recess 11 may have a width defined by the largest width of the inclined portion 11b. The micro-LED 100 on the transfer head or the first substrate 1001 may fall in a direction toward the loading recess 11 from a position thereabove, the position being within the range of the width of the opening of the loading recess 11. In this case, the micro-LED 100 may be accommodated in the loading recess 11 even if alignment accuracy between the transfer head 1000 or the first substrate 1001 and the micro-LED position error correcting carrier 10 is relatively low. Therefore, when the width of the inclined portion 11b forming the opening of the loading recess 11 is large, the range that can accommodate the position error between the loading recess 11 and the micro-LED 100 may be increased.

The bottom surface 11a on which the micro-LED 100 is seated may hold the micro-LED 100 using holding force. This holding force may be at least one of vacuum suction force, Van der Waals force, electrostatic force, and magnetic force. In the present disclosure, it will be described as an example that the micro-LED 100 is held on the bottom surface 11a using vacuum suction force.

When the bottom surface 11a holds the micro-LED 100 using vacuum suction force, a member capable of generating a holding force may be provided under the inclined portion 11b. Thereby, the bottom surface 11a may hold the micro-LED 100 using vacuum suction force.

On the other hand, the bottom surface 11a may only function to allow the micro-LED 100 to be seated thereon. In this case, the micro-LED 100 may be seated on the bottom surface 11a through the inclined portion 11b. When the bottom surface 11a only functions to allow the micro-LED 100 to be seated thereon, the bottom surface 11a may be configured by closing a lower end of the inclined portion 11b without provision of a separate member, or may be configured by providing a member that does not have a function of generating a holding force. The bottom surface 11a may function to hold the micro-LED 100 using holding force or may only function to allow the micro-LED 100 to be seated thereon without using holding force.

Hereinafter, it will be described as an example that the bottom surface 11a holds the micro-LED 100 using holding force. The bottom surface 11a enables the micro-LED 100 to be more accurately accommodated in the loading recess 11 by using the holding force.

As illustrated in FIG. 3, the member capable of generating a holding force is provided under the inclined portion 11b. Thereby, the bottom surface 11a may be formed by closing the lower end of the inclined portion 11b. The member forming the bottom surface 11a may generate a holding force. Therefore, the bottom surface 11a may hold the micro-LED 100 using the holding force.

The micro-LED position error correcting carrier 10 includes the non-loading surface 12 around the loading recess 11. The non-loading surface 12 may be configured as a horizontal surface to correspond to the position of a micro-LED 100 not to be accommodated in the loading recess 11.

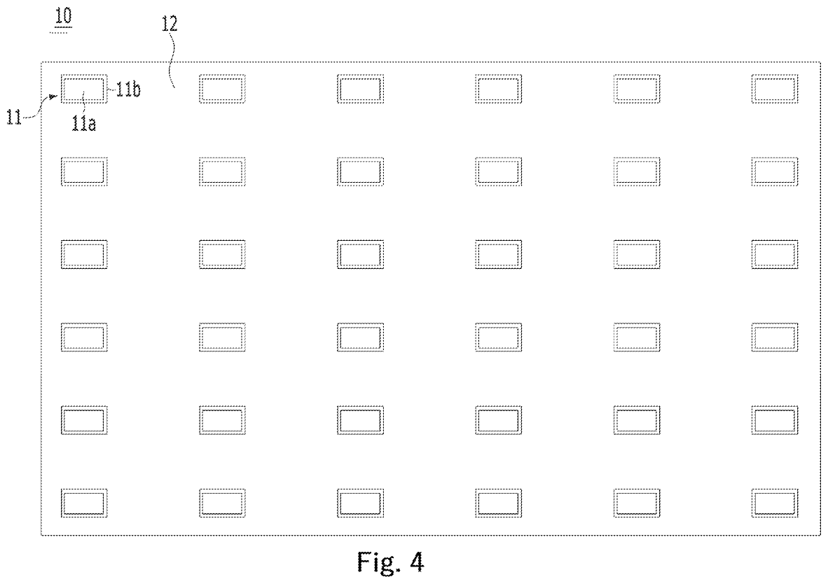

FIG. 4 is a view illustrating the micro-LED position error correcting carrier 10 according to the exemplary embodiment of the present disclosure as viewed from above. As illustrated in FIG. 4, multiple loading recesses 11 are arranged spaced apart from each other. The non-loading surface 12 is provided around the loading recesses 11. The loading recesses 11 may be arranged spaced apart from each other in consideration of transferring red, green, and blue micro-LEDs 100 implementing pixels to the second substrate 1002.

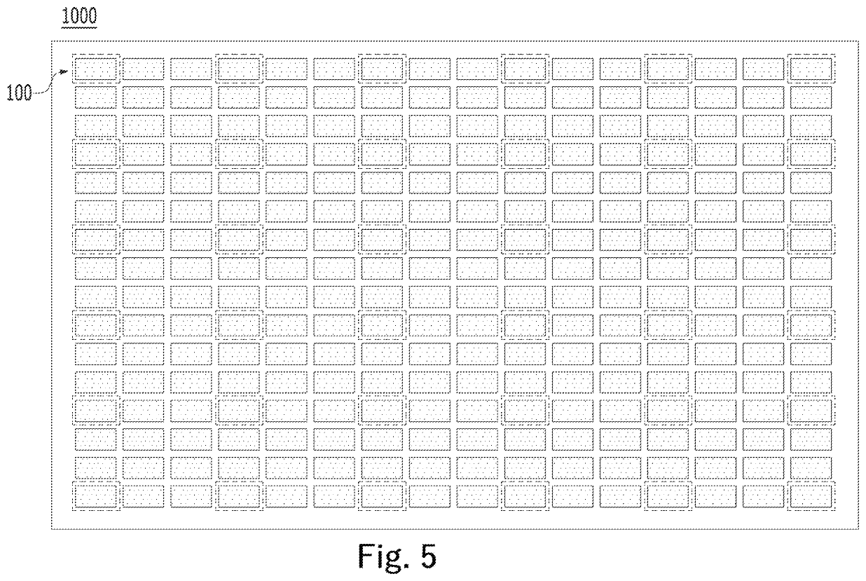

FIG. 5 is a view illustrating a holding surface of the transfer head 1000 on which the micro-LEDs 100 of the first substrate are held as viewed from below. As illustrated in FIG. 5, the micro-LEDs 100 on the first substrate 1001 may be arranged at a one-fold pitch distance in the x- and y-directions.

The loading recesses 11 may be arranged in a spaced-apart relationship. Thereby, when respectively transferred to the second substrate 1002, the red, green, and blue micro-LEDs 100a, 100b, and 100c may be transferred in a state in which their position errors are corrected. For example, the micro-LED position error correcting carrier 10 corrects a position error of the red micro-LEDs 100a. In this case, the micro-LED position error correcting carrier 10 directly receives the red micro-LEDs 100a from the first substrate 1001. Only red micro-LEDs 100a corresponding to the loading recesses 11 are accommodated in the loading recesses 11. In other words, of the red micro-LEDs 100a of the first substrate 1001, only the red micro-LEDs 100a at positions corresponding to the loading recesses 11 are transferred to and received in the loading recesses 11. The red micro-LEDs 100a accommodated in the loading recesses 11 of the micro-LED position error correcting carrier 10 may be held by the transfer head 1000 which is a micro-LED transfer means. In this case, the red micro-LEDs 100a are held on the transfer head 1000 by being spaced apart from each other at a separation distance equal to that between the loading recesses 11. The held red micro-LEDs 100a are transferred to the second substrate 1002. The red micro-LEDs 100a are transferred to the second substrate 1002 in a state in which the separation distance therebetween capable of implementing pixels is predetermined due to the loading recesses 11. The green and blue micro-LEDs 100b and 100c are transferred to positions within the range of the separation distance between the red micro-LEDs 100a. The green and blue micro-LEDs 100b and 100c may be transferred to the second substrate 1002 by being also spaced apart from each other at a separation distance that is predetermined due to the loading recesses 11. The second substrate 1002 to which the red, green, and blue micro-LEDs 100a, 100b, and 100c are transferred may implement pixels. In the above, it has been described as an example that the red micro-LEDs 100a are firstly transferred to the second substrate 1002, and then the green and blue micro-LEDs 100b and 100c are transferred in sequence. However, the order of transferring the micro-LEDs ML to the second substrate 1002 is not limited thereto. The micro-LEDs may be transferred to the second substrate 1002 in an order such that one red micro-LED 100a, one green micro-LED 100b, and one blue micro-LED 100c form one pixel.

On the other hand, the micro-LED position error correcting carrier 10 may correct a position error of micro-LEDs 100 received from the transfer head 1000. For example, the received micro-LEDs are red micro-LEDs 100a. As illustrated in FIG. 5, the red micro-LEDs 100a may be held on the transfer head 1000. The transfer head 1000 may hold the red micro-LEDs 100a having an arrangement as illustrated in FIG. 5. The transfer head 1000 may transfer the red micro-LEDs 100a to the micro-LED position error correcting carrier 10. The red micro-LEDs 100a held on the transfer head 1000 may be accommodated in the loading recesses 11 by holding force exerted thereon by respective bottom surfaces 11a of the loading recesses 11. A part of the red micro-LEDs 100a indicated by dotted borders illustrated in FIG. 5 may be red micro-LEDs located at positions corresponding to the loading recesses 11. As such, only the red micro-LEDs 100a at the positions corresponding to the loading recesses 11 may be transferred to the micro-LED position error correcting carrier 10. Then, position errors of the green and blue micro-LEDs 100b and 100c may also be corrected through the micro-LED position error correcting carrier 10. Since the loading recesses 11 of the micro-LED position error correcting carrier 10 are arranged in a spaced-apart relationship, this makes pixel implementation of the second substrate 1002 more efficient. A detailed description will be given later of a process in which position errors of the red, green and blue micro-LEDs 100a, 100b, and 100c are corrected through the micro-LED position error correcting carrier 10 before being transferred to the second substrate 1002 and then are transferred to the second substrate 1002 to implement pixels.

The non-loading surface 12 is provided around the loading recesses 11. Since the loading recesses 11 are arranged in a spaced-apart relationship and are surrounded by the non-loading surface 12, even if respective openings of the loading recesses 11 have large widths, the interference between adjacent loading recesses 11 does not occur due to the provision of the non-loading surface 12. In other words, even if the widths of the openings of the loading recesses 11 become large, a problem in which the adjacent loading recesses 11 invade each other's areas to interfere with each other does not occur. This may enable the loading recesses 11 to have the openings with widths that allow the micro-LEDs 100 to be efficiently received in the loading recesses 11.

The micro-LED position error correcting carrier 10 may include a guide member having inclined portions 11b and the non-loading surface 12, and a support member 14 coupled to a lower portion of the guide member 13 so as to close respective lower ends of the inclined portions 11b to form the loading recesses 11.

Referring back to FIG. 3, the micro-LED position error correcting carrier 10 may include the guide member having the inclined portions 11b and the non-loading surface 12, and the support member 14 coupled to the lower portion of the guide member 13 so as to close the lower ends of the inclined portions 11b to form the loading recesses 11.

In the guide member 13 having the inclined portions 11b and the non-loading surface 12, the lower ends of the inclined portions 11b are closed as the support member 14 is coupled to the lower portion of the guide member 13. The bottom surfaces 11a are formed thereby under the inclined portions 11b, resulting in forming the loading recesses 11 each having the bottom surface 11a and the inclined portion 11b.

Each of the loading recesses 11 may have a tapered quadrangular cross-section due to having the inclined portion 11b. The inclined portion 11b may extend upward from the bottom surface 11a to have a width larger than that of the bottom surface 11a. Thereby, a micro-LED 100 to be accommodated in the loading recess 11 may be accurately seated on the bottom surface 11a of the loading recess 11 along the inclined portion 11b.

The guide member 13 may be made of an elastic material. Thereby, when the micro-LEDs 100 transferred from the transfer head 1000 or the first substrate 1001 come into contact with the micro-LED position error correcting carrier 10, the guide member 13a may exert a buffering effect.

Specifically, the micro-LEDs 100 are transferred from the transfer head 1000 or the first substrate 1001 to the micro-LED position error correcting carrier 10. As the transfer head 1000 or the first substrate 1001 is lowered toward the guide member 13, respective lower surfaces of the micro-LEDs 100 on the transfer head 1000 or the first substrate 1001 may come into contact with the guide member 13. Specifically, the lower surfaces of the micro-LEDs 100 may come into contact with an upper surface of the non-loading surface 12 of the guide member 13.

When the means for transferring the micro-LEDs 100 is the first substrate 1001, a laser lift-off (LLO) process may be performed to transfer the micro-LEDs 100 of the first substrate 1001 to the micro-LED position error correcting carrier 10. The LLO process may be selectively performed only on micro-LEDs 100 located at positions corresponding to the loading recesses 11. During the LLO process, the micro-LEDs 100 may undergo a bouncing phenomenon. In order to prevent a case in which the micro-LEDs 100 fail to be accommodated in the loading recesses 11 due to the bouncing phenomenon, the first substrate 1001 may be further lowered toward the micro-LED position error correcting carrier 10. At this time, micro-LEDs 100 located at positions corresponding to the non-loading surface 12 of the guide member 13 come into intimate contact with the non-loading surface 12. Due to being made of an elastic material, the guide member 13 may perform a buffer function so that the micro-LEDs 100 coming into intimate contact with the non-loading surface 12 are not damaged. Thereby, even if the bouncing phenomenon of the micro-LEDs 100 occurs, the position error of the micro-LEDs 100 in the loading recesses 11 may be more efficiently corrected, and the micro-LEDs 100 not accommodated in the loading recesses 11 may be prevented from being damaged.

The support member 14 coupled to the lower portion of the guide member 13 may hold the micro-LEDs 100 using holding force. In this case, the holding force used by the support member 14 may be at least one of vacuum suction force, Van der Waals force, electrostatic force, and magnetic force. Since the support member 14 is a configuration for forming the loading recesses 11, the bottom surfaces 11a of the loading recesses 11 may hold the micro-LEDs 100 using the holding force of the support member 14. Hereinafter, it will be described that the support member 14 uses vacuum suction force.

The support member 14 may be configured as a porous member having arbitrary or vertical pores. The support member 14 may vacuum-hold the received micro-LEDs 100 by applying a vacuum to the pores of the porous member.

The porous member is configured as powders, a coating film, or bulk. The powder may have various shapes such as a sphere, a hollow sphere, a fiber, and a tube. The powder may be used as it is in some cases, but it is also possible to prepare a coating film or a bulk shape with the powder as a starting material.

In the support member 14 having the arbitrary pores, a plurality of pores having a certain arrangement or disordered pore structure may be connected to each other, so that the flow of air may exist in a horizontal direction. Thereby, the vacuum may be transferred to the bottom surfaces 11a of the multiple loading recesses 11. The support member having the arbitrary pores may form a uniform vacuum pressure to hold the micro-LEDs 100.

On the other hand, the support member 14 may be configured as the porous member having the vertical pores. The support member 14 has air flow paths that are formed by the vertical pores passing through the support member 14 from top to bottom. The support member 14 may vacuum-hold the micro-LEDs 100 in the loading recesses 11 by applying a vacuum to the pores.

The support member 14 may be made of an anodic aluminum oxide film. In the present disclosure, it will be described that the support member 14 is made of the anodic aluminum oxide film.

The anodic aluminum oxide film has pores having a certain arrangement. The anodic aluminum oxide film refers to a film formed by anodizing a metal that is a base material, and the pores refer to pores formed in the anodic aluminum oxide film during the process of forming the anodic aluminum oxide film by anodizing the metal. First, in case where the metal as the base material is aluminum (Al) or an aluminum alloy, the anodization of the base material forms an anodic aluminum oxide film consisting of anodized aluminum oxide (Al₂O₃) on a surface of the base material. The anodic aluminum oxide film has a barrier layer in which no pores are formed and a porous layer in which pores are formed. The barrier layer is positioned on the base material, and the porous layer is positioned on the barrier layer. In a state in which the anodic aluminum oxide film having the barrier layer and the porous layer is formed on the base material, when the base material is removed, only the anodic aluminum oxide film consisting of anodized aluminum oxide (Al₂O₃) remains.

The resulting anodic aluminum oxide film has the pores that have a uniform diameter, are formed in a vertical shape, and have a regular arrangement. Therefore, when the barrier layer is removed, the pores have a structure vertically passing through the anodic aluminum oxide film from top to bottom, thereby facilitating the generation of the vacuum pressure in a vertical direction.

Due to the pores of vertical shape, air flow paths of vertical shape may be formed inside the anodic aluminum oxide film. An internal width of each of the pores has a size of several to several hundred nm. For example, when the size of each of the micro-LEDs to be vacuum-held is 30 μm×30 μm and the internal width of each of the pores is several nm, the micro-LEDs 100 may be vacuum-held through approximately tens of millions of pores.

Meanwhile, the transfer head 1000 for transferring the micro-LEDs 100 to the micro-LED position error correcting carrier 10 may be made of an anodic aluminum oxide film. The micro-LED transfer head 1000 may hold the micro-LEDs 100 through pores of the anodic aluminum oxide film. In addition, the support member 14 forming the loading recesses 11 may have a hole formed by etching at least a portion of the support member 14. Thereby, the support member 14 may have a larger vacuum pressure than the transfer head 1000. Specifically, the hole may be formed in the support member 14 at a position corresponding to the bottom surface 11a of each of the loading recesses 11. The positions where the respective holes are formed may be positions that close the bottom surfaces 11a of the loading recesses 11. The holes may pass through the support member 14 from top to bottom. Each of the holes may have a width that is smaller than that of each of the bottom surfaces 11a of the loading recesses 11 and smaller than that of each of the micro-LEDs 100. Due to the holes, the support member 14 may have a vacuum pressure larger than that of a holding portion of the transfer head 1000. This may enable the micro-LEDs corresponding to the loading recesses 11 to be effectively detached and held.

The micro-LED position error correcting carrier 10 may correct the position error of the micro-LEDs 100 by accommodating the micro-LEDs 100 in the loading recesses 11 as described above. Preferably, positions of the micro-LEDs 100 are corrected before being transferred to the second substrate 1002. This may result in minimizing an alignment error between the micro-LEDs 100 and the bonding pads 1002a of the second substrate 1002.

Before being transferred to the second substrate 1002, the separation distance of the micro-LEDs 100 may be predetermined according to the arrangement of the loading recesses 11 of the micro-LED position error correcting carrier 10, and the position error thereof is corrected accurately. The present disclosure not only corrects the position error of the micro-LEDs 100 through the loading recesses 11, but also enables formation of the separation distance therebetween in consideration of pixel implementation. This may result in reducing a defect rate due to position errors and thereby increasing efficiency of micro-LED transfer.

The micro-LED position error correcting carrier 10 as described above may be provided in a micro-LED transfer system 1 to correct the position error of the micro-LEDs 100.

First, a description will be given of a process in which the micro-LED transfer system 1 corrects a position error of micro-LEDs by including a micro-LED position error correcting carrier 10 and a transfer head 1000.

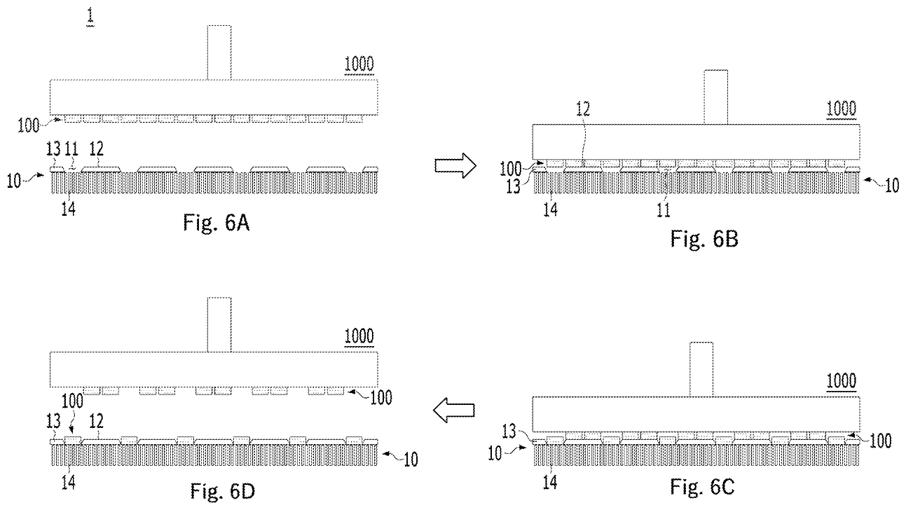

FIGS. 6A to 6D is a view illustrating the micro-LED transfer system 1 according to the present disclosure including the micro-LED position error correcting carrier 10 and the transfer head 1000. Hereinafter, it will be described that the transfer head 1000 is capable of holding the micro-LEDs 100 using vacuum suction force. However, holding force of the transfer head 1000 is not limited thereto.

The micro-LED position error correcting carrier 10 receives the micro-LEDs 100 whose positions are to be corrected from the transfer head 1000. FIGS. 6A to 6D schematically illustrates a process in which the micro-LED position error correcting carrier 10 receives the micro-LEDs 100 from the transfer head 1000 and corrects the position error of the micro-LEDs 100.

The micro-LED transfer system 1 may include: the transfer head 1000 for transferring the micro-LEDs 100; and the micro-LED position error correcting carrier 10 including loading recesses 11 each of which has a bottom surface 11a and an inclined portion 11b and allows a micro-LED 100 to be accommodated therein, and a non-loading surface 12 provided around the loading recesses 11.

The micro-LED position error correcting carrier 10 provided in the micro-LED transfer system 1 according to the present disclosure may hold the micro-LEDs 100 using holding force or accommodate the micro-LEDs 100 without using holding force.

Hereinafter, it will be described that the micro-LED position error correcting carrier 10 is configured by combining a guide member 13 having the respective loading recesses 11 and the non-loading surface 12 and a support member 14 using holding force. Therefore, the loading recesses 11 may hold and accommodate the micro-LEDs 100 therein using the holding force. The non-loading surface 12 may have a shape surrounding the peripheries of the loading recesses 11.

The transfer head 1000 for transferring the micro-LEDs 100 to the micro-LED position error correcting carrier 10 may include a holding portion for holding the micro-LEDs 100. When the transfer head 1000 holds micro-LEDs 100 on a first substrate 1001 and transfers the same to the micro-LED position error correcting carrier 10, the transfer head 1000 may include holding portions arranged at a pitch distance equal to that between the micro-LEDs 100 on the first substrate 1001 in the x- and y-directions. Thereby, the transfer head 1000 may collectively hold the micro-LEDs 100 of the first substrate 1001 and transfer the same to the micro-LED position error correcting carrier 10.

First, a state in which the transfer head 1000 collectively holds the micro-LEDs 100 of the first substrate 1001 will be described with reference to FIG. 5. As illustrated in FIG. 5, the micro-LEDs 100 of the first substrate 1001 are collectively held on the transfer head 1000 through the holding portions of the transfer head 1000 arranged at a pitch distance equal to that between the micro-LEDs 100 of the first substrate 1001 in the x- and y-directions. The pitch distance between the holding portions of the transfer head 1000 and that between the micro-LEDs 100 of the first substrate 1001 are equal to each other. Therefore, the arrangement of the micro-LEDs 100 illustrated in FIG. 5 may be an arrangement of the micro-LEDs 100 of the first substrate 1001.

Thereafter, as illustrated in FIG. 6A, the transfer head 1000 on which the micro-LEDs 100 of the first substrate 1001 are held is positioned above the micro-LED position error correcting carrier 10.

Then, as illustrated in FIG. 6B, the transfer head 1000 is lowered toward the micro-LED position error correcting carrier 10. The transfer head 1000 may be lowered to a position where an upper surface of the non-loading surface 12 of the micro-LED position error correcting carrier 10 and respective lower surfaces of micro-LEDs 100 corresponding to the non-loading surface 12 come into contact with each other. In this case, a lowering stop position of the transfer head 1000 may be a position before the upper surface of the non-loading surface 12 and the lower surfaces of the micro-LEDs 100 come into contact with each other. However, in order to more accurately transfer, to the loading recesses 11 of the micro-LED position error correcting carrier 10, micro-LEDs 100 corresponding thereto, it may be preferable that the lowering stop position is a position where the upper surface of the non-loading surface 12 and the lower surfaces of the micro-LEDs 100 corresponding to the non-loading surface 12 come into contact with each other. The guide member 13 including the respective inclined portions 11b and the non-loading surface 12 may be made of an elastic material. Therefore, when the micro-LEDs 100 are transferred to the loading recesses 11, even if the non-loading surface 12 and the micro-LEDs 100 corresponding thereto come into contact with each other, the micro-LEDs 100 corresponding to the non-loading surface 12 may be prevented from being damaged.

Then, as illustrated in FIG. 6C, the transfer head 1000 transfers the micro-LEDs 100 to the micro-LED position error correcting carrier 10. The micro-LED position error correcting carrier 10 may include the loading recesses 11 having a pitch distance three-fold greater than an x- and y-direction pitch distance between the micro-LEDs 100 of the first substrate 1001. Thereby, the micro-LEDs 100 held on the transfer head 1000 may be transferred to the loading recesses 11 by being spaced apart from each other at a three-fold pitch distance in the x- and y-directions in FIG. 5. This makes pixel implementation more efficient when the micro-LEDs 100 whose position error is corrected by the micro-LED position error correcting carrier 10 are transferred to a second substrate 1002 using the transfer head 1000 or a separate transfer means.

Among the micro-LEDs 100 held on the transfer head 1000, the micro-LEDs 100 corresponding to the loading recesses 11 are transferred to the micro-LED position error correcting carrier 10, while the micro-LEDs 100 corresponding to the non-loading surface 12 are not transferred to the micro-LED position error correcting carrier 10.

Referring to FIGS. 6C and 6D, in the micro-LED position error correcting carrier 10 illustrated in FIGS. 6A to 6D, a leftmost loading recess in the drawing is referred to as a first loading recess. Meanwhile, among the micro-LEDs 100 held on the transfer head 1000 illustrated in FIGS. 6A to 6D, a leftmost micro-LED 100 in the drawing is referred to as a first micro-LED. In this case, the first loading recess corresponds to the first micro-LED, so that the first micro-LED is accommodated in the first loading recess. The loading recesses 11 are provided in the micro-LED position error correcting carrier 10 by being arranged at a three-fold pitch distance in the x- and y-directions of the micro-LEDs 100 of the first substrate 1001. Therefore, a fourth micro-LED is accommodated in a second loading recess spaced apart from the first loading recess at a three-fold pitch distance. In addition, a seventh micro-LED is accommodated in the third loading recess spaced apart from the second loading recess at a three-fold pitch distance. Then, micro-LEDs corresponding to fourth, fifth, and sixth loading recesses are transferred and received therein, respectively.

As described above, only the micro-LEDs 100 corresponding to the respective loading recesses 11 are transferred to the micro-LED position error correcting carrier 10 to be accommodated in the loading recesses 11. Each of the loading recesses 11 has the bottom surface 11a and the inclined portion 11b. The micro-LEDs 100 may be accurately guided to the respective bottom surfaces 11a through the respective inclined portions 11b of the loading recesses 11. The support member 14 for holding the micro-LEDs 100 by using holding force is provided under the guide member 13. Therefore, the bottom surfaces 11a of the loading recesses 11 may hold the micro-LEDs 100 using the holding force of the support member 14. The holding force of the support member 14 may be larger than that of the transfer head 1000. This may enable the micro-LEDs 100 to be more easily seated in the loading recesses 11.

As illustrated in FIG. 6D, only the micro-LEDs 100 corresponding to the respective loading recesses 11 are transferred to the micro-LED position error correcting carrier 10. The transfer head 1000 is then lifted. The transfer head 1000 may transfer micro-LEDs 100 that are not transferred to the micro-LED position error correcting carrier 10 to another position error correcting carrier.

As illustrated in FIG. 6D, the micro-LEDs 100 seated on the micro-LED position error correcting carrier 10 may be transferred to the second substrate 1002 such as a circuit board 1002 through a transfer means such as the transfer head 1000.

In the micro-LED transfer system 1 described with reference to FIGS. 6A to 6D, the micro-LEDs 100 whose positions are to be corrected through the micro-LED position error correcting carrier 10 may be red, green, and blue micro-LEDs 100a, 100b, and 100c. The respective micro-LEDs 100a, 100b, and 100c may be transferred to the micro-LED position error correcting carrier 10 through the transfer head 1000. By performing the same process as above, the positions of the respective micro-LEDs 100a, 100b, and 100c may be corrected by the micro-LED position error correcting carrier 10.

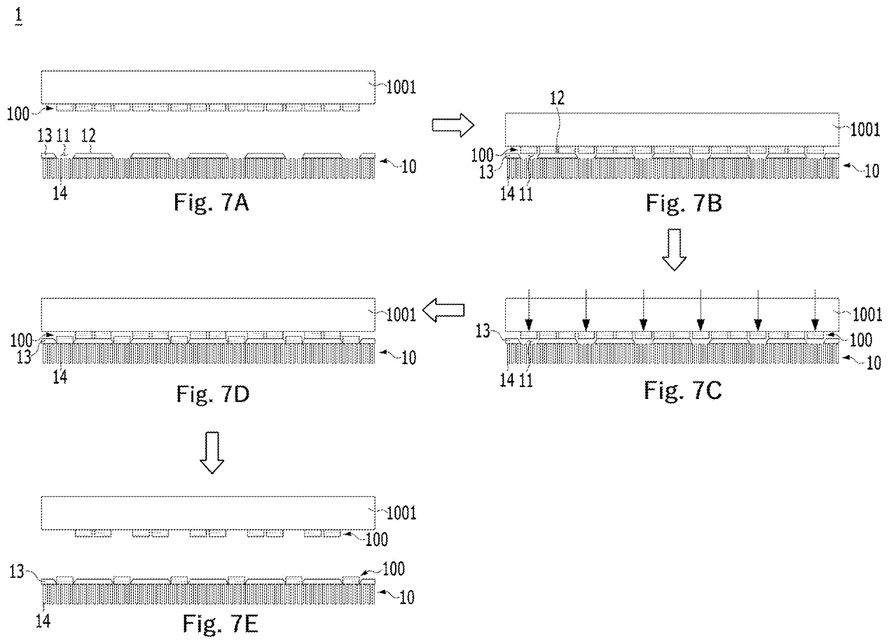

Hereinafter, with reference to FIGS. 7A to 7E, a description will be given of a process in which a micro-LED transfer system 1 according to the present disclosure corrects a position error of micro-LEDs 100 by including a micro-LED position error correcting carrier 10 and a substrate 1001 including a first substrate 1001. When the micro-LED transfer system 1 includes the substrate 1001 and corrects the position error of the micro-LEDs 100 through the micro-LED position error correcting carrier 10, all configurations except for the substrate 1001, which is a means for transferring the micro-LEDs 100, may remain the same as those of the micro-LED transfer system 1 including the transfer head 1000 described above. Therefore, a redundant description will be omitted.

FIGS. 7A to 7E is a view illustrating the micro-LED transfer system 1 according to the present disclosure including the micro-LED position error correcting carrier 10 and the substrate 1001 on which the micro-LEDs 100 are provided. The substrate 1001 of the micro-LED transfer system 1 may include the first substrate 1001 on which the micro-LEDs 100 are provided. Therefore, for convenience, the substrate 1001 will be described with the same reference numeral as the first substrate 1001.

The micro-LED transfer system 1 may include: the substrate 1001 on which the micro-LEDs 100 are provided; and the micro-LED position error correcting carrier 10 including loading recesses 11 each of which has a bottom surface 11a and an inclined portion 11b and allows a micro-LED 100 to be accommodated therein, and a non-loading surface 12 provided around the loading recesses 11.

The micro-LED position error correcting carrier 10 may directly receive the micro-LEDs 100 whose positions are to be corrected from the substrate 1001.

The micro-LEDs 100 may be arranged on the substrate 1001 at a one-fold pitch distance in the x- and y-directions in FIG. 5.

The micro-LEDs 100 of the substrate 1001 may be in a state in which a position error is occurred. The substrate 1001 may be a growth substrate. In case of the growth substrate, LLO has to be used to remove the micro-LEDs 100 from the growth substrate, and a position error of the micro-LEDs 100 may occur in the process of removing the micro-LEDs 100 through the LLO. When the micro-LEDs 100 having the position error are transferred as they are to a second substrate 1002 using a transfer means such as a transfer head 1000, an alignment error between the micro-LEDs 100 and bonding pads 1002a of the second substrate 1002 occurs, resulting in a defective product. Therefore, before the transfer head 1000 holds the micro-LEDs 100 provided on the substrate 1001 and transfers the same to the second substrate 1002, the position error may be corrected through the micro-LED position error correcting carrier 10.

As illustrated in FIG. 7A, the substrate 1001 on which the micro-LEDs 100 are provided is positioned above the micro-LED position error correcting carrier 10.

Then, as illustrated in FIG. 7B, the substrate 1001 is lowered toward the micro-LED position error correcting carrier 10. The substrate 1001 may be lowered to a position where an upper surface of the non-loading surface 12 of the micro-LED position error correcting carrier 10 and respective lower surfaces of micro-LEDs 100 corresponding to the non-loading surface 12 come into contact with each other. Alternatively, the substrate 1001 may be lowered to a position before the upper surface of the non-loading surface 12 and the lower surfaces of the micro-LEDs 100 come into contact with each other. However, when the micro-LEDs 100 of the substrate 1001 are transferred to the micro-LED position error correcting carrier 10, an LLO process is performed. During the LLO process, the micro-LEDs 100 may undergo a bouncing phenomenon. In order to prevent a case in which the micro-LEDs 100 fail to be accommodated in the loading recesses 11 due to the bouncing phenomenon, it may be preferable that the substrate 1001 is lowered to the position where the upper surface of the non-loading surface 12 of the micro-LED position error correcting carrier 10 and the lower surfaces of the micro-LEDs 100 of the substrate 1001 corresponding to the non-loading surface 12 come into contact with each other. Hereinafter, it will be described that the LLO process is performed after the contact between the non-loading surface and the lower surfaces of the micro-LEDs 100 of the substrate 1001 corresponding thereto.

As illustrated in FIG. 7B, as the substrate 1001 is lowered, the non-loading surface 12 and the lower surfaces of the micro-LEDs 100 of the substrate 1001 corresponding thereto come into contact with each other. Then, as illustrated in FIG. 7(c), the LLO process is selectively performed on micro-LEDs 100 corresponding to the respective loading recesses 11. The LLO process may be selectively performed only on the micro-LEDs 100 located at positions corresponding to the loading recesses 11. Arrows illustrated in FIG. 7C mean that the LLO process is selectively performed on the micro-LEDs 100 corresponding to the loading recesses 11. Thereby, among the micro-LEDs 100 provided on the substrate 1001, the micro-LEDs 100 corresponding to the loading recesses 11 are transferred to the micro-LED position error correcting carrier 10, while the micro-LEDs 100 corresponding to the non-loading surface 12 are not transferred to the micro-LED position error correcting carrier 10.

The LLO process is performed on a first micro-LED corresponding to a first loading recess in FIG. 7C. In addition, the LLO process is performed on a fourth micro-LED corresponding to a second loading recess In addition, the LLO process is performed on respective micro-LEDs corresponding to third to sixth loading recesses. During the LLO process, the micro-LEDs 100 may undergo a bouncing phenomenon due to gas pressure. Therefore, it is preferable to further lower the substrate 1001 to minimize a height difference between the loading recesses 11 and the micro-LEDs 100 corresponding thereto. A guide member 13 including the non-loading surface 12 may be made of an elastic material. The non-loading surface 12 may have a shape surrounding the peripheries of the loading recesses 11. Therefore, when the substrate 1001 is further lowered and thereby the micro-LEDs 100 corresponding to the non-loading surface 12 come into contact therewith, the guide member 13 may function as a buffer while being compressed. Therefore, during the LLO process for the micro-LEDs 100 corresponding to the loading recesses 11, the micro-LEDs 100 corresponding to the non-loading surface 12 may be prevented from being damaged.

As illustrated in FIG. 7(c), the LLO process is selectively performed on the micro-LEDs 100 corresponding to the respective loading recesses 11.

Then, as illustrated in FIG. 7D, the micro-LEDs 100 are accommodated in the loading recesses 11. Each of the loading recesses 11 has the bottom surface 11a and the inclined portion 11b. The micro-LEDs 100 may be accurately seated on the respective bottom surfaces 11a through the respective inclined portions 11b of the loading recesses 11. In other words, the inclined portions 11b may function as position guides so that the micro-LEDs 100 are accurately positioned on the bottom surfaces 11a of the loading recesses 11. The bottom surfaces 11a of the loading recesses 11 may be formed by coupling a support member 14 using holding force to a lower portion of the guide member 13. Therefore, the bottom surfaces 11a of the loading recesses 11 may hold the micro-LEDs 100 using the holding force of the support member 14. The loading recesses 11 hold the micro-LEDs 100 therein using the holding force. With the holding force of the bottom surface 11a exerting on the micro-LEDs 100, the micro-LEDs 100 seated on the bottom surfaces 11a through the inclined portions 11b of the loading recesses 11 may be more accurately held in the loading recesses 11.

As illustrated in FIG. 7E, the substrate 1001 on which the micro-LEDs 100, which correspond to the non-loading surface 12 and are not transferred to the micro-LED position error correcting carrier 10, are provided is lifted. The micro-LEDs 100 that are not transferred to the micro-LED position error correcting carrier 10 to another position error correcting carrier.

As illustrated in FIG. 7E, the micro-LEDs 100 seated on the micro-LED position error correcting carrier 10 may be transferred to the second substrate 1002 such as a circuit board 1002 through a transfer means such as the transfer head 1000. A description will be given later of a process in which the micro-LEDs 100 seated on the micro-LED position error correcting carrier 10 are transferred to the second substrate 1002 such as the circuit board 1002.

In the micro-LED transfer system 1 described with reference to FIGS. 7A to 7E, the micro-LEDs 100 whose positions are to be corrected through the micro-LED position error correcting carrier 10 may be red, green, and blue micro-LEDs 100a, 100b, and 100c. The respective micro-LEDs 100a, 100b, and 100c may be transferred to the micro-LED position error correcting carrier 10 from the substrate 1001. By performing the same process as above, the positons of the respective micro-LEDs 100a, 100b, and 100c may be corrected by the micro-LED position error correcting carrier 10.

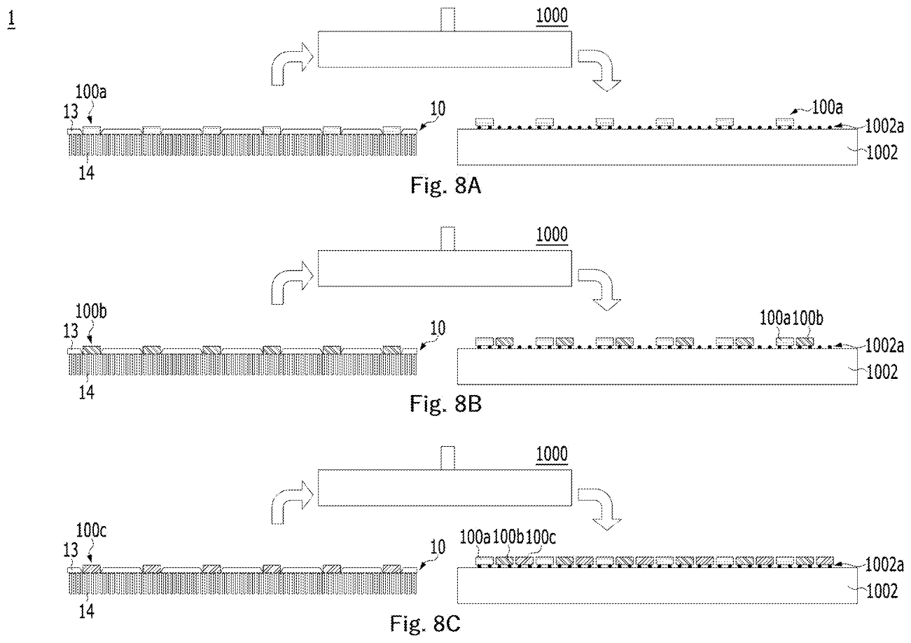

FIGS. 8A to 8C is a view illustrating a process in which micro-LEDs 100 seated on a micro-LED position error correcting carrier 10 are transferred to a circuit board 1002 having bonding pads 1002a connected to terminals of the micro-LEDs 100 in a micro-LED transfer system 1.

The micro-LED transfer system 1 may include: the micro-LED position error correcting carrier 10 including loading recesses 11 each of which has a bottom surface 11a and an inclined portion 11b and allows a micro-LED 100 to be accommodated therein, and a non-loading surface 12 provided around the loading recesses 11; the circuit board 1002 having the bonding pads 1002a connected to the terminals of the micro-LEDs 100; and a transfer head 1000 transferring the micro-LEDs 100 seated on the micro-LED position error correcting carrier 10 to the circuit board 1002.

In this case, the circuit board 1002 having the bonding pads 1002a connected to the terminals of the micro-LEDs 100 may be the same as the above-described second substrate 1002. Therefore, the circuit board 1002 will be described with the same reference numeral as the second substrate 1002.

In addition, the transfer head 1000 transferring the micro-LEDs 100 to the circuit board 1002 may be the same as the above-described transfer head 1000 transferring the micro-LEDs 100 to the micro-LED position error correcting carrier 10. Therefore, the transfer heads 1000 referred to in the present disclosure use the same reference numeral.

The micro-LEDs 100 seated on the micro-LED position error correcting carrier 10 provided in the micro-LED transfer system 1 may be red, green, or blue micro-LEDs 100a, 100b, or 100c.

In this case, the micro-LEDs 100 seated on the micro-LED position error correcting carrier 10 may be micro-LEDs 100 received from the transfer head 1000. Alternatively, the micro-LEDs 100 seated on the micro-LED position error correcting carrier 10 may be micro-LEDs received from a substrate 1001 including a first substrate 1001.

Meanwhile, the micro-LEDs may be transferred to the circuit board 1002 so that one red micro-LED 100a, one green micro-LED 100b, and one blue micro-LED 100c form one pixel in each of the x- and y-directions of the circuit board 1002. Specifically, the micro-LEDs may be transferred to the circuit board 1002 so that the red, green, and blue micro-LEDs 100a, 100b, and 100c are sequentially arranged in the x-direction of the circuit board 1002, and multiple pixels are formed in the x-direction thereof. In addition, the micro-LEDs may be transferred to the circuit board 1002 so that the red, green, and blue micro-LEDs 100a, 100b, and 100c are sequentially arranged in the y-direction of the circuit board 1002, and multiple pixels are formed in the y-direction thereof.

Hereinafter, only a cross-section of the circuit board 1002 in the x-direction is illustrated as an example. Therefore, a description will be given of a process in which the multiple pixels are formed by transferring the red, green, and blue micro-LEDs 100a, 100b, and 100c in the x-direction of the circuit board 1002. However, this is only an example of an arrangement in which pixels are implemented on the circuit board 1002. Therefore, the arrangement in which the pixels of the circuit board 1002 are implemented is not limited thereto.

In addition, the order of transferring the red, green, or blue micro-LEDs 100c to the circuit board 1002, which will be described below, is also not limited.

Hereinafter, it will be described that the red micro-LEDs 100a are firstly transferred to the circuit board 1002 among the micro-LEDs whose positions are corrected by the micro-LED position error correcting carrier 10. The green micro-LEDs 100b and the blue micro-LEDs 100c are then sequentially transferred to the circuit board 1002.

Micro-LEDs illustrated in FIG. 8A are the red micro-LEDs 100a. The micro-LED transfer system 1 may transfer the red micro-LEDs 100a seated on the micro-LED position error correcting carrier 10 to the circuit board 1002. In this case, the red micro-LEDs 100a are transferred to the circuit board 1002 by the transfer head 1000. The transfer head 1000 holds the red micro-LEDs 100a whose position error is corrected by the micro-LED position error correcting carrier 10. At this time, the loading recesses 11 of the micro-LED position error correcting carrier 10 are arranged spaced apart from each other. A pitch distance between the loading recesses 11 is three-fold greater than an x- and y-direction pitch distance between the micro-LEDs 100 of the first substrate 1001. The micro-LED position error correcting carrier 10 transfers only red micro-LEDs 100a corresponding to the loading recesses 11. Therefore, when the transfer head 1000 holds the red micro-LEDs 100a from the micro-LED position error correcting carrier 10, the red micro-LEDs 100a may be held by being spaced apart from each other at a three-fold pitch distance in the x- and y-directions. Therefore, the red micro-LEDs 100a are held on the transfer head 1000 at positions corresponding to the loading recesses 11 by being spaced apart from each other at a three-fold pitch distance in the x- and y-directions in FIG. 5.

The transfer head 1000 collectively transfers the red micro-LEDs 100a whose position error is corrected by the micro-LED position error correcting carrier 10 to the circuit board 1002. This may result in minimizing an alignment error between the red micro-LEDs 100a mounted on the circuit board 1002 and the bonding pads 1002a.

As illustrated on the left side in FIG. 8A, the position error of the red micro-LEDs 100a is corrected by the micro-LED position error correcting carrier 10. The transfer head 1000 holds the red micro-LEDs 100a and collectively transfers the red micro-LEDs 100a to the circuit board 1002 as illustrated in the right side in FIG. 8(a). The transfer head 1000 is in a state in which the red micro-LEDs 100a are held thereon by being spaced apart from each other at a three-fold pitch distance in the x- and y-directions in FIG. 5. Therefore, the red micro-LEDs 100a are transferred to the circuit board 1002 by being spaced apart from each other at a three-fold pitch distance in the x-direction in FIG. 8A. At this time, the red micro-LEDs 100a may be mounted with the alignment error with respect to the bonding pads 1002a minimized. This is because the position error of the red micro-LEDs 100a is corrected in advance by the micro-LED position error correcting carrier 10 before the red micro-LEDs 100a are transferred to the circuit board 1002.

As described above, by correcting the position error through the micro-LED position error correcting carrier 10 before the micro-LEDs 100 including the red micro-LEDs 100a are transferred to the circuit board 1002, the present disclosure may minimize an alignment error between the micro-LEDs 100 and the bonding pads 1002a. This provides an effect of minimizing mass production of defective products and improving micro-LED transfer efficiency.

Then, the transfer head 1000 may transfer the green micro-LEDs 100b to the circuit board 1002. As illustrated on the left side in FIG. 8B, the green micro-LEDs 100b are seated on the micro-LED position error correcting carrier 10 and a position error thereof is corrected. In this case, the micro-LED position error correcting carrier 10 may be a micro-LED position error correcting carrier 10 provided corresponding to the green micro-LEDs 100b differently from the micro-LED position error correcting carrier 10 on which the red micro-LEDs 100a are seated.

The green micro-LEDs 100b seated on the micro-LED position error correcting carrier 10 are held by the transfer head 1000. The green micro-LEDs 100b are held on the transfer head 1000, with a pitch distance equal to that between the loading recesses 11. The transfer head 1000 may then transfer the held green micro-LEDs 100b to the circuit board 1002. At this time, the green micro-LEDs 100b may be collectively transferred in the x-direction of the circuit board 1002 at a three-fold pitch distance while being spaced apart from the red micro-LEDs 100a. The transfer head 1000 may collectively transfer the green micro-LEDs 100b by moving to the right side in the drawing by a distance equal to a one-fold pitch distance in the x-direction of the red micro-LEDs 100a previously transferred to the circuit board 1002.

Before being transferred to the circuit board 1002, the positon error of the green micro-LEDs 100b may be corrected through the micro-LED position error correcting carrier 10, so that an alignment error thereof with respect to the bonding pads 1002a may be minimized.

Then, the transfer head 1000 may transfer the blue micro-LEDs 100c to the circuit board 1002. As illustrated on the left side in FIG. 8C, the blue micro-LEDs 100c are seated on the micro-LED position error correcting carrier 10. The blue micro-LEDs 100c are in a state in which a position error is corrected by the micro-LED position error correcting carrier 10. The transfer head 1000 holds the blue micro-LEDs 100c seated on the micro-LED position error correcting carrier 10. At this time, the blue micro-LEDs 100c are held on the transfer head 1000, with a pitch distance equal to that between the loading recesses 11. The transfer head 1000 may then collectively transfer the held blue micro-LEDs 100c to the circuit board 1002. At this time, the blue micro-LEDs 100c may be collectively transferred in the x-direction of the circuit board 1002 at a three-fold pitch distance while being spaced apart from the green micro-LEDs 100b. The transfer head 1000 may collectively transfer the blue micro-LEDs 100c by moving to the right side in the drawing by a distance equal to a one-fold pitch distance in the x-direction of the red micro-LEDs 100a previously transferred to the circuit board 1002.

Before being transferred to the circuit board 1002, the position error of the blue micro-LEDs 100c may be corrected through the micro-LED position error correcting carrier 10, so that an alignment error thereof with respect to the bonding pads 1002a may be minimized.

The circuit board 1002 to which all the red, green, and blue micro-LEDs 100a, 100b, and 100c are transferred may have a form in which the red, green, and blue micro-LEDs 100a, 100b, and 100c are sequentially arranged in the x- and y-directions to form multiple pixel groups.

The form in which as the red, green, and blue micro-LEDs 100a, 100b, and 100c are sequentially arranged in the x-direction of the circuit board 1002, the micro-LEDs 100a, 100b, or 100c of the same color are arranged in the y-direction to form the multiple pixel groups may be formed while the transfer head 1000 reciprocates multiple times between the micro-LED position error correcting carrier 10 and the circuit board 1002. Specifically, the transfer head 1000 may reciprocate nine times.

On the other hand, the micro-LEDs of the same color may be arranged in a diagonal direction to form multiple pixel groups. First, the transfer head 1000 holds red micro-LEDs 100a from the micro-LED position error correcting carrier 10 on which the red micro-LEDs 100a are seated. The transfer head 1000 collectively transfers the red micro-LEDs 100a to the circuit board 1002. The above process may be performed during one-time transfer.

Then, the transfer head 1000 holds green micro-LEDs 100b from the micro-LED position error correcting carrier on which the green micro-LEDs 100b are seated. The transfer head 1000 collectively transfers the green micro-LEDs 100b to the circuit board 1002 by moving to the right side in the drawing by a distance equal to a one-fold pitch distance in the x-direction of the red micro-LEDs 100a firstly transferred to the circuit board 1002. The above process may be performed during two-time transfer.

Then, the transfer head 1000 holds blue micro-LEDs 100c from the micro-LED position error correcting carrier 10 on which the blue micro-LEDs 100c are seated. The transfer head 1000 collectively transfers the blue micro-LEDs 100c to the circuit board 1002 by moving to the right side in the drawing by a distance equal to a one-fold pitch distance in the x-direction of the green micro-LEDs 100b previously transferred to the circuit board 1002. The above process may be performed during three-time transfer.

Then, the transfer head 1000 holds blue micro-LEDs 100c from the micro-LED position error correcting carrier 10 on which the blue micro-LEDs 100c are seated. The transfer head 1000 collectively transfers the blue micro-LEDs 100c to the circuit board 1002 by moving to the lower side in the drawing by a distance equal to a one-fold pitch distance in the y-direction of the green micro-LEDs 100b firstly transferred to the circuit board 1002. The above process may be performed during four-time transfer.

Then, the transfer head 1000 holds red micro-LEDs 100a from the micro-LED position error correcting carrier 10 on which the red micro-LEDs 100a are seated. The transfer head 1000 collectively transfers the red micro-LEDs 100a to the circuit board 1002 by moving to the right side in the drawing by a distance equal to a one-fold pitch distance in the x-direction of the blue micro-LEDs 100c transferred to the circuit board 1002 during the four-time transfer. The above process may be performed during five-time transfer.

Then, the transfer head 1000 holds green micro-LEDs 100b from the micro-LED position error correcting carrier on which the green micro-LEDs 100b are seated. The transfer head 1000 collectively transfers the green micro-LEDs 100b to the circuit board 1002 by moving to the right side in the drawing by a distance equal to a one-fold pitch distance in the x-direction of the red micro-LEDs 100a transferred to the circuit board 1002 during the five-time transfer. The above process may be performed during six-time transfer.

Then, the transfer head 1000 holds green micro-LEDs 100b from the micro-LED position error correcting carrier 10 on which the green micro-LEDs 100b are seated. The transfer head 1000 collectively transfers the green micro-LEDs 100b to the circuit board 1002 by moving to the lower side in the drawing by a distance equal to a one-fold pitch distance in the y-direction of the blue micro-LEDs 100c transferred to the circuit board 1002 during the four-time transfer. The above process may be performed during seven-time transfer.

Then, the transfer head 1000 holds blue micro-LEDs 100c from the micro-LED position error correcting carrier 10 on which the blue micro-LEDs 100c are seated. The transfer head 1000 collectively transfers the blue micro-LEDs 100c to the circuit board 1002 by moving to the right side in the drawing by a distance equal to a one-fold pitch distance in the x-direction of the green micro-LEDs 100b transferred to the circuit board 1002 during the seven-time transfer. The above process may be performed during eight-time transfer.

Then, the transfer head 1000 holds red micro-LEDs 100a from the micro-LED position error correcting carrier 10 on which the red micro-LEDs 100a are seated. The transfer head 1000 collectively transfers the red micro-LEDs 100a to the circuit board 1002 by moving to the right side in the drawing by a distance equal to a one-fold pitch distance in the x-direction of the blue micro-LEDs 100c transferred to the circuit board 1002 during the eight-time transfer. The above process may be performed during nine-time transfer.

When the multiple pixel groups are formed by sequentially arranging the red, green, and blue micro-LEDs 100a, 100b, and 100c in the diagonal direction of the circuit board 1002, this may be achieved by reciprocating the transfer head 1000 nine times between the micro-LED position error correcting carrier 10 and the circuit board 1002 as described above. However, this may vary depending on the form in which pixels are configured on the circuit board 1002.

In the present disclosure, through nine-time transfer as described above, the micro-LEDs 100 whose position errors are corrected by the micro-LED position error correcting carrier 10 may be transferred to the circuit board 1002. As a result, the multiple pixels are formed on the circuit board 1002, thereby achieving pixel implementation.

The present disclosure may correct the position errors of the micro-LEDs 100 through the micro-LED position error correcting carrier 10 before the micro-LEDs 100 are transferred to the second substrate 1002 on which the bonding pads 1002a are provided. In addition, the present disclosure may correct the position error of the micro-LEDs 100 of the transfer head 1000 in which a holding position error is occurred as the transfer head 1000 holds the micro-LEDs 100 having the position error. Thereby, the high-precision transfer head 1000 for holding the micro-LEDs 100 whose position error is corrected through the micro-LED position error correcting carrier 10 may have further increased transfer efficiency. In addition, the present disclosure may minimize the alignment error between the bonding pads 1002a and the micro-LEDs 100 in the second substrate 1002, such as the circuit board 1002 on which the bonding pads 1002a are provided. This provides an effect of improving micro-LED transfer efficiency, and reducing occurrence rate of defective products due to the alignment error with the bonding pads 1002a.

As described above, the present disclosure has been described with reference to the exemplary embodiments. However, those skilled in the art will appreciate that various modifications, additions, and substitutions are possible, without departing from the scope and spirit of the present disclosure as disclosed in the accompanying claims.

[Description of the Reference Numerals in the Drawings]

| | |
|---|---|
| 1: micro-LED transfer system | |
| 10: micro-LED position error correcting carrier | |
| 11: loading recess | |
| 11a: bottom surface | 11b: inclined portion |
| 12: non-loading surface | 13: guide member |
| 14: support member | 100: micro-LED |
| 1000: transfer head | |
| 1001: first substrate, substrate | |
| 1002: second substrate, circuit board | |
| 1002a: bonding pad | |

1. A micro-LED position error correcting carrier, comprising:
a loading recess having a bottom surface and an inclined portion and allowing a micro-LED to be accommodated therein; and
a non-loading surface provided around the loading recess.

2. The micro-LED position error correcting carrier of claim 1, wherein the bottom surface holds the micro-LED using holding force.

3. The micro-LED position error correcting carrier of claim 2, wherein the holding force is at least one of vacuum suction force, Van der Waals force, electrostatic force, and magnetic force.

4. A micro-LED position error correcting carrier, comprising:
a guide member having an inclined portion and a non-loading surface; and
a support member coupled to a lower portion of the guide member to form the loading recess by closing a lower end of the inclined portion.

5. The micro-LED position error correcting carrier of claim 4, wherein the support member holds a micro-LED using holding force.

6. The micro-LED position error correcting carrier of claim 4, wherein the support member comprises a porous member having arbitrary or vertical pores, and
the support member vacuum-holds a micro-LED by applying a vacuum to the pores.

7. The micro-LED position error correcting carrier of claim 4, wherein the guide member is made of an elastic material.

8. A micro-LED transfer system, comprising:
a transfer head configured to transfer micro-LEDs; and
a micro-LED position error correcting carrier including a loading recess that has a bottom surface and an inclined portion and allows a micro-LED to be accommodated therein, and a non-loading surface provided around the loading recess,
wherein among the micro-LEDs held on the transfer head, a micro-LED corresponding to the loading recess is transferred to the micro-LED position error correcting carrier, while a micro-LED corresponding to the non-loading surface is not transferred to the micro-LED position error correcting carrier.

9-10. (canceled)
